(19) United States
(12) Patent Application Publication
(10) Pub. No.: US 2024/0037315 A1
(43) Pub. Date: Feb. 1, 2024

(54) TRANSISTOR CHARACTERISTIC SIMULATION DEVICE, TRANSISTOR CHARACTERISTIC SIMULATION METHOD, AND NON-TRANSITORY COMPUTER READABLE MEDIUM STORING TRANSISTOR CHARACTERISTIC SIMULATION PROGRAM

(71) Applicant: Mitsubishi Electric Corporation, Tokyo (JP)

(72) Inventors: Tomohiro OTSUKA, Tokyo (JP); Yutaro YAMAGUCHI, Tokyo (JP); Koji YAMANAKA, Tokyo (JP)

(73) Assignee: Mitsubishi Electric Corporation, Tokyo (JP)

(21) Appl. No.: 18/378,444

(22) Filed: Oct. 10, 2023

Related U.S. Application Data
(63) Continuation of application No. PCT/JP2021/020770, filed on Jun. 1, 2021.

(51) Int. Cl. G06F 30/398

(52) U.S. Cl. CPC G06F 30/398

(57) ABSTRACT

A transistor characteristics simulation device uses a transistor equivalent circuit model, in which the transistor equivalent circuit model includes a trap equivalent circuit for modifying a level of a trap of a transistor by an electric field intensity, the trap equivalent circuit corresponding to a physical model of Poole-Frenkel effect.

### CROSS REFERENCE TO RELATED APPLICATION

This application is a Continuation of PCT International Application No. PCT/JP2021/020770, filed on Jun. 1, 2021, which is hereby expressly incorporated by reference into the present application.

### TECHNICAL FIELD

The present disclosure relates to a simulation technique of transistor characteristics.

### BACKGROUND ART

In general, a transistor equivalent circuit model is used to calculate the characteristics of a transistor. Non-Patent Literature 1 discloses a transistor equivalent circuit model including a trap equivalent circuit represented by an RC circuit in addition to a parasitic component and a current source.

### CITATION LIST

### NON-PATENT LITERATURE

Non-Patent Literature 1: T. Otsuka et. al. “Study of Self heating Effect of GaN HEMTs with Buffer Traps by Low Frequency S-parameters Measurements and TCAD Simulation,” IEEE BiCMOS and Compound Semiconductor Integrated Circuits and Technology Symposium (BCICTS), Nov. 3-6, 2019, Nashville, Tennessee, USA, 3b.2.

### SUMMARY OF INVENTION

### TECHNICAL PROBLEM

According to the transistor equivalent circuit model of Non-Patent Literature 1, since the trap equivalent circuit is provided, the influence of the trap in the transistor on the characteristics of the transistor can be considered to some extent.

However, in the conventional trap equivalent circuit, since the time constant of the trap is constant, there is a problem that the calculation result does not match the measurement result in simulation of transient response characteristics under a plurality of voltage conditions.

The present disclosure has been made to solve such a problem, and an object of the present disclosure is to provide a transistor characteristics simulation technology capable of further matching a calculation result and a measurement result in simulation of transient response characteristics under a plurality of voltage conditions.

### SOLUTION TO PROBLEM

A transistor characteristics simulation device according to an embodiment of the present disclosure is a transistor characteristic simulation device using a transistor equivalent circuit model, wherein the transistor equivalent circuit model comprises a trap equivalent circuit for modifying a level of a trap of a transistor by an electric field intensity, the trap equivalent circuit corresponding to a physical model of Poole-Frenkel effect.

### ADVANTAGEOUS EFFECTS OF INVENTION

According to the transistor characteristics simulation device according to the embodiment of the present disclosure, it is possible to further match a calculation result and a measurement result in simulation of transient response characteristics under a plurality of voltage conditions.

### BRIEF DESCRIPTION OF DRAWINGS

FIG. 1 is a diagram illustrating a transistor equivalent circuit model according to a first embodiment.

FIG. 2 is a diagram illustrating a comparison between a calculation result and a measurement result using a trap equivalent circuit according to the first embodiment for a time constant of a trap in transient response characteristics under a plurality of voltage conditions.

FIG. 3 is a hardware configuration diagram of the transistor characteristics simulation device.

FIG. 4 is a flowchart of a transistor characteristics simulation method.

FIG. 5 is a diagram illustrating a transistor equivalent circuit model according to a second embodiment.

FIG. 6 is a diagram illustrating a transistor equivalent circuit model according to a third embodiment.

FIG. 7 is a diagram illustrating a conventional transistor equivalent circuit model.

FIG. 8 is a diagram illustrating a comparison between a calculation result and a measurement result using a conventional trap equivalent circuit for a time constant of a trap in transient response characteristics under a plurality of voltage conditions.

### DESCRIPTION OF EMBODIMENTS

Hereinafter, various embodiments according to the present disclosure will be described in detail with reference to the drawings. Note that components denoted by the same or similar reference numerals in the drawings have the same or similar configurations or functions, and redundant description of such components will be omitted.

### First Embodiment.

### <Configuration of Transistor Equivalent Circuit Model>

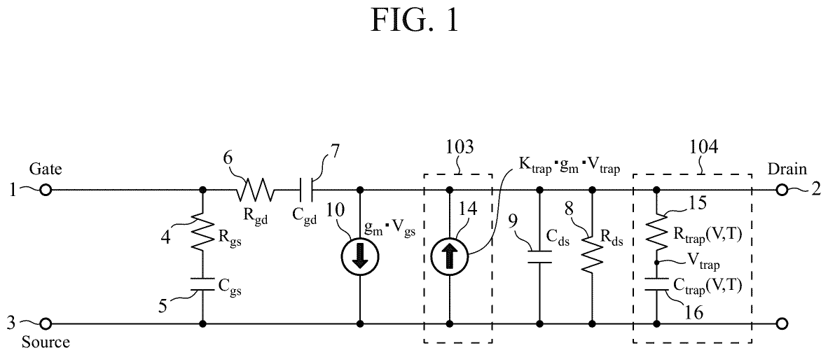

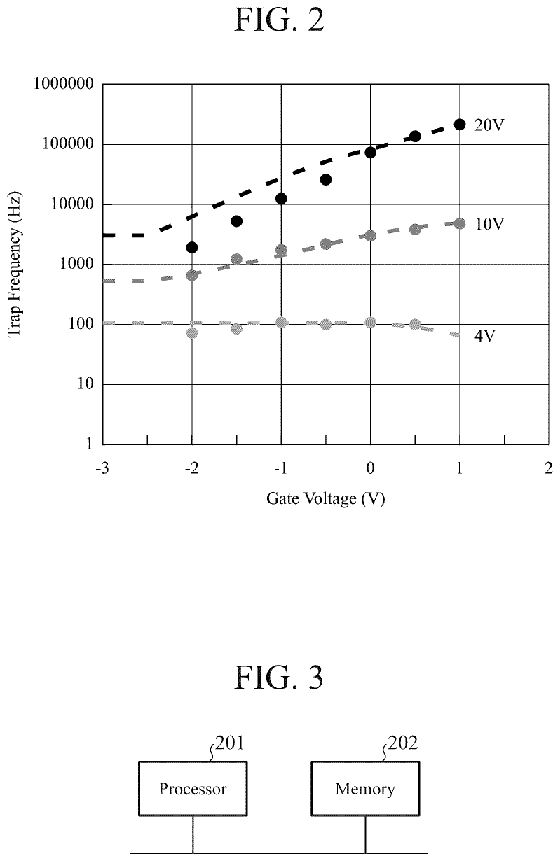

A transistor equivalent circuit model according to a first embodiment of the present disclosure will be described with reference to FIGS. 1 and 2. Note that it is sufficient that the transistor represented by the transistor equivalent circuit model is a transistor having an insulator as a structure of the transistor, and examples of the target transistor include a metal-oxide-semiconductor field-effect transistor (MOSFET), for example. FIG. 1 is a diagram illustrating the transistor equivalent circuit model according to the first embodiment. As illustrated in FIG. 1, the transistor equivalent circuit model according to the first embodiment includes a gate electrode 1, a drain electrode 2, a source electrode 3, a gate source resistor (Rgs) 4, a gate source capacitor (Cgs) 5, a gate drain resistor (Rgd) 6, a gate drain capacitor (Cgd) 7, a drain source resistor (Rds) 8, a drain source capacitor (Cds) 9, a current source (gₘ·Vgs) 10, a trap equivalent circuit 103 represented by a current source (Ktrap*gₘ*Vtrap) 14 indicating an influence of a current due to a trap, and a trap equivalent circuit 104 including a trap resistor (Rtrap (V, T)) 15 and a trap capacitor (Ctrap (V, T)) 16 and expressing a time constant of a trap disposed between the source electrode and the drain electrode. The trap resistor (Rtrap (V, T)) 15 is a circuit parameter having voltage dependence and temperature dependence. The trap capacitor (Ctrap (V, T)) 16 is also a circuit parameter having voltage dependence and temperature dependence. Ktrap is a feedback constant, and the voltage Vtrap applied to both ends of the trap capacitor (Ctrap (V, T)) 16 is fed back to the current source (Ktrap*gₘ*Vtrap) 14 by Ktrap*gₘ*Vtrap. Note that gₘ is transconductance.

### <Operation of Trap Equivalent Circuit>

Next, the operation of the trap equivalent circuit will be described. Note that, since the configuration of the transistor equivalent circuit model according to the present disclosure is similar to the conventional configuration except for the trap equivalent circuit, the operation of the trap equivalent circuit will be described below.

The transistor equivalent circuit model of FIG. 1 is a circuit model reflecting a physical model of the Poole-Frenkel effect. First, a physical model of the Poole-Frenkel effect will be described. The Poole-Frenkel effect is a physical model describing that a trap level at which electrons are trapped in an insulator changes under the influence of electric field intensity. Equation (1) shows an equation relating to the time constant of the trap for a case in which there is no influence of the Poole-Frenkel effect, and Equation (2) shows an equation relating to the time constant of the trap for a case in which there is an influence of the Poole-Frenkel effect. fₜᵣₐₚ represents the frequency of the reciprocal of the time constant of the trap (Hereinafter, referred to as a trap frequency.). In Equations (1) and (2), vₜₕ represents a thermal velocity, Nc represents an effective state density of a conduction band, 6 represents a trap capture cross-sectional area, Ea represents a trap level, k represents a Boltzmann constant, T represents a channel temperature in a steady state, and ΔT represents a magnitude of an increase in the channel temperature during operation. In Equation (2), the physical model of the Poole-Frenkel effect is reflected on the time constant (trap frequency) of the trap by modifying the trap level Ea by the electric field intensity F and the coefficient β in the exponential function of exp. Since the trap level Ea becomes smaller due to the influence of the electric field intensity as the electric field intensity increases due to the Poole-Frenkel effect, the time constant of the trap decreases and the trap frequency fₜᵣₐₚ increases.

$$\begin{matrix}{f}_{trap} = \frac{{v}_{th} {N}_{c} σ}{exp [ ( {E}_{a} ) / k \cdot ( T + Δ T ) ]} & ( 1 ) \\ {f}_{trap} = \frac{{v}_{th} {N}_{c} σ}{exp [ ( {E}_{a} - β \sqrt{F} ) / k \cdot ( T + Δ T ) ]} & ( 2 )\end{matrix}$$

In Equation (2), the trap level Ea is modified by the electric field intensity F, but it is difficult to use the electric field intensity as it is in the equivalent circuit model. Accordingly, it is conceivable to replace the electric field intensity with a voltage that can be used in the equivalent circuit model. By replacing the electric field intensity with the voltage, the physical model of the Poole-Frenkel effect can be made to correspond to the circuit model in the trap equivalent circuit of FIG. 1. Equation (3) is obtained by converting the electric field intensity F in Equation (2) into the output voltage V. Since the output voltage V is proportional to the electric field intensity of the channel through which the drain current flows, the trap level can be modified by β and V also in the case of Equation (3). Therefore, Equation (3) is also an equation relating to the time constant of the trap corresponding to the physical model of the Poole-Frenkel effect.

$${f}_{trap} = \frac{{v}_{th} {N}_{c} σ}{exp [ ( {E}_{a} - β \sqrt{V} ) / k \cdot ( T + Δ T ) ]} \qquad ( 3 )$$

Next, a method of making the physical formula of Equation (3) regarding the time constant of the trap corresponding to the physical model correspond to the time constant in the trap equivalent circuit will be described.

In order to do so, here, a transistor equivalent circuit model including a conventional trap equivalent circuit will be described with reference to FIG. 7. FIG. 7 is a diagram illustrating a transistor equivalent circuit model including conventional trap equivalent circuits 101 and 102. A time constant of the trap using the conventional trap equivalent circuit 102 is represented by a product of Rtrap and Ctrap and is constant as expressed by Equation (4). Equation (4) does not include a parameter having voltage dependence, and Equation (4) corresponds to the equation regarding the time constant of the trap of Equation (1) that does not correspond to the physical model in the physical formula.

Equation (5) shows an equation relating to a time constant of a trap using the trap equivalent circuit 104 in the transistor equivalent circuit model of FIG. 1 of the present disclosure. Equation (5) regarding the time constant of the trap in the trap equivalent circuit 104 of the present disclosure corresponds to Equation (3) indicating the time constant of the trap corresponding to the physical model of the Poole-Frenkel effect. In the equation regarding the time constant of the trap in the equivalent circuit model of Equation (5), an exponential function including the output voltage dependence and the temperature dependence expressed by exp is used in order to make the time constant of the trap correspond to Equation (3) considering the influence of the Poole-Frenkel effect. As shown in Equation (5), in order to cause the time constant of the trap to correspond to the equation of the Poole-Frenkel effect including the exponential function, not only the output voltage V indicating the influence of the electric field intensity but also the term k (T+ΔT) including the influence of the temperature rise are included in the same exponential function. Therefore, in order to cause the physical model of the Poole-Frenkel effect to correspond to the circuit model, it is conceivable to modify the time constant of the trap using an exponential function in which the voltage dependence and the temperature dependence are integrated as in Equation (5).

$$\begin{matrix}{f}_{trap} = \frac{1}{{R}_{trap} \cdot {C}_{trap}} & ( 4 ) \\ {f}_{trap} = \frac{1}{{R}_{trap} \cdot {C}_{trap}} \cdot exp [ \frac{β \sqrt{V}}{k \cdot ( T + Δ T )} ] & ( 5 )\end{matrix}$$

Next, the correspondence of the equation regarding the time constant of the trap equivalent circuit of Equation (5) to the trap equivalent circuit 104 will be described. From Equation (5), in order to make the physical model of the Poole-Frenkel effect correspond to the circuit model, it is conceivable to modify the time constant of the trap by expressing the time constant of the trap using an exponential function in which the influence of the output voltage and the temperature are integrated. For this purpose, it is conceivable that both the trap resistor (Rtrap (V, T)) 15 and the trap capacitor (Ctrap (V, T)) 16 constituting the trap equivalent circuit 104 are expressed as an exponential function in which the influence of the output voltage and the temperature are integrated. From such consideration, it is conceivable to express the trap equivalent circuit parameter Rtrap (V, T) representing the trap resistor (Rtrap (V, T)) 15 and the trap equivalent circuit parameter Ctrap (V, T) representing the trap capacitor (Ctrap (V, T)) 16 as Equations (6) and (7), respectively. In both Equations (6) and (7), the voltage dependence and the temperature dependence are expressed by one exponential function. Both Rtrap in Equation (6) and Ctrap in Equation (7) are constants. As shown in Equations (6) and (7), when the output voltage increases, both the trap resistance and the trap capacitance in the trap equivalent circuit decrease. When the output voltage increases, the trap resistance and the trap capacitance decrease, so that the time constant of the trap in Equation (5) decreases. This shows the same effect as that the time constant of the trap decreases by modifying the trap level by the electric field intensity in the physical formula of Equation (2). Therefore, the trap equivalent circuit 104 including the trap resistor 15 expressed by Equation (6) and the trap capacitor 16 expressed by Equation (7) can implement a trap equivalent circuit made to correspond to the physical model of the Poole-Frenkel effect.

$$\begin{matrix}{R}_{trap} ( V , T ) = {R}_{trap} \cdot exp [ - \frac{β \sqrt{V}}{2 k \cdot ( T + Δ T )} ] & ( 6 ) \\ {C}_{trap} ( V , T ) = {C}_{trap} \cdot exp [ - \frac{β \sqrt{V}}{2 k \cdot ( T + Δ T )} ] & ( 7 )\end{matrix}$$

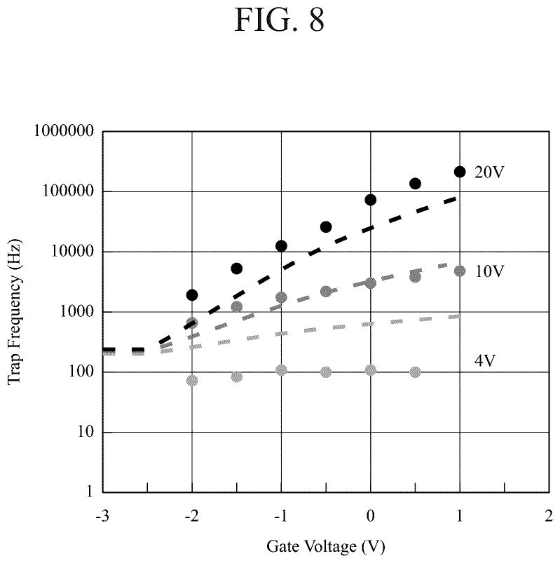

The effect of the trap equivalent circuit described above was verified by calculating the time constant of the trap in the transient response characteristics under a plurality of voltage conditions. The verification result will be described with reference to FIGS. 2 and 8. FIG. 2 is a calculation result of the time constant of the trap in the case of using the trap equivalent circuit of the present disclosure, and FIG. 8 is a calculation result of the time constant of the trap in the case of using the conventional trap equivalent circuit. In FIGS. 2 and 8, a broken line represents a calculation result using a trap equivalent circuit, and a plot point represents a measurement result. In the verification of FIGS. 2 and 8, as a plurality of voltage conditions, a range of −2 to 1 V for a gate voltage (Vgs) and three conditions of 4 V, 10 V, and 20 V for a drain voltage (Vds) are verified, where the vertical axis represents the frequency (trap frequency) of the reciprocal of the time constant of the trap, and the horizontal axis represents the gate voltage. In the calculation regarding the conventional structure of FIG. 8, the time constant of the trap by the trap equivalent circuit is expressed by Equation (4). Since

Equation (4) does not correspond to the physical model of the Poole-Frenkel effect, the calculation result regarding the time constant of the trap in the transient response characteristics under the plurality of voltage conditions does not match the measurement result. In the calculations relating to the structure of the present disclosure of FIG. 2, the time constant of the trap by the trap equivalent circuit is expressed by Equation (5). Since Equation (5) corresponds to the physical model of the Poole-Frenkel effect, the calculation result regarding the time constant of the trap in the transient response characteristics under the plurality of voltage conditions can be matched with the measurement result. From the results of FIG. 2, it can be confirmed that the structure of the present disclosure can further match the calculation result and the measurement result in simulation of transient response characteristics under a plurality of voltage conditions. Furthermore, by using the structure of the present disclosure, the transistor equivalent circuit model can be made to correspond to the physical model.

### <Hardware Configuration>

Next, a hardware configuration of the transistor characteristics simulation device using the transistor circuit model including the trap equivalent circuit described above will be described with reference to FIG. 3. The transistor characteristics simulation device is implemented by a computer including a processor 201 and a memory 202 as illustrated in FIG. 3, and performs simulation by the processor 201 reading a program stored in the memory 202 and executing the read program. The memory 202 stores a program and data for creating a transistor equivalent circuit model. Examples of the memory include a nonvolatile or volatile semiconductor memory such as a random access memory (RAM), a read-only memory (ROM), a flash memory, an erasable programmable read only memory (EPROM), or an electrically erasable programmable read-only memory (EEPROM), a magnetic disk, a flexible disk, an optical disk, a compact disk, a mini disk, and a DVD. The program and the data for creating the transistor equivalent circuit model may be stored in a portable storage medium.

### <Simulation Method>

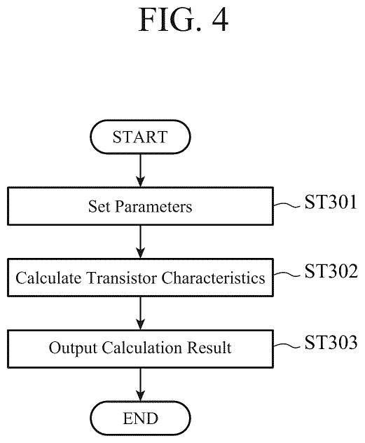

Next, a transistor characteristics simulation method performed using the transistor circuit model including the trap equivalent circuit described above will be described with reference to FIG. 4.

In step ST301, the transistor characteristics simulation device receives setting values related to various parameters of the transistor circuit model including the trap equivalent circuit illustrated in FIG. 1 via an input device (not illustrated) such as a keyboard.

In step ST302, the transistor characteristics simulation device simulates the transistor characteristics using the transistor circuit model including the trap equivalent circuit illustrated in FIG. 1 and the setting values received in step ST301.

In step ST303, the transistor characteristics simulation device outputs the simulation result to an output device (not illustrated) such as a monitor.

### Second Embodiment.

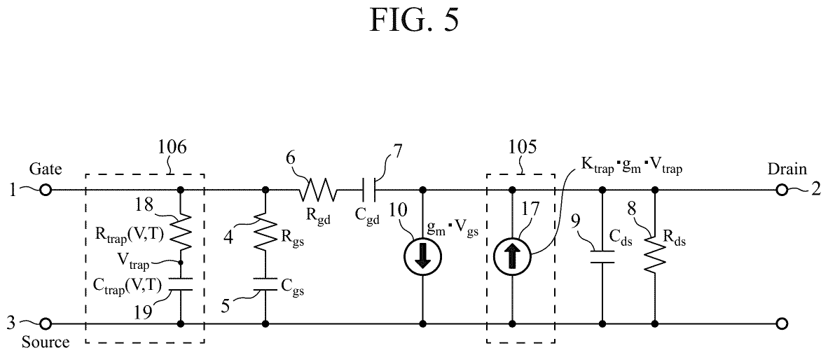

Next, a transistor equivalent circuit model according to a second embodiment will be described with reference to FIG. 5. As illustrated in FIG. 5, the transistor equivalent circuit model according to the second embodiment includes a gate electrode 1, a drain electrode 2, a source electrode 3, a gate source resistor (Rgs) 4, a gate source capacitor (Cgs) 5, a gate drain resistor (Rgd) 6, a gate drain capacitor (Cgd) 7, a drain source resistor (Rds) 8, a drain source capacitor (Cds) 9, a current source (gₘ·Vgs) 10, a trap equivalent circuit 105 represented by a current source (Ktrap*gₘ*Vtrap) 17 that indicates the influence of current due to trap, and a trap equivalent circuit 106 that includes a trap resistor (Rtrap (V, T)) 18 and a trap capacitor (Ctrap (V, T)) 19 and represents a time constant of a trap disposed between the gate electrode and the source electrode. As described above, in the transistor equivalent circuit model according to the second embodiment, the trap equivalent circuit 106 representing the time constant of the trap is disposed at a position different from the case of the first embodiment. With such a configuration, in the second embodiment, the influence of the trap between the gate electrode and the source electrode can be calculated. Even in the case of the trap between the gate electrode and the source electrode as in the second embodiment, since the trap level is affected by the output voltage proportional to the electric field intensity, it is conceivable to consider a physical model of the Poole-Frenkel effect for modifying the influence of the electric field intensity. When it is taken into consideration, the time constant of the trap may be modified by the output voltage and the temperature using Equations (5), (6), and (7) described in the first embodiment.

Since the hardware configuration and the simulation method of the transistor characteristics simulation device according to the second embodiment are similar to those in the first embodiment, the description thereof will be omitted.

### Third Embodiment.

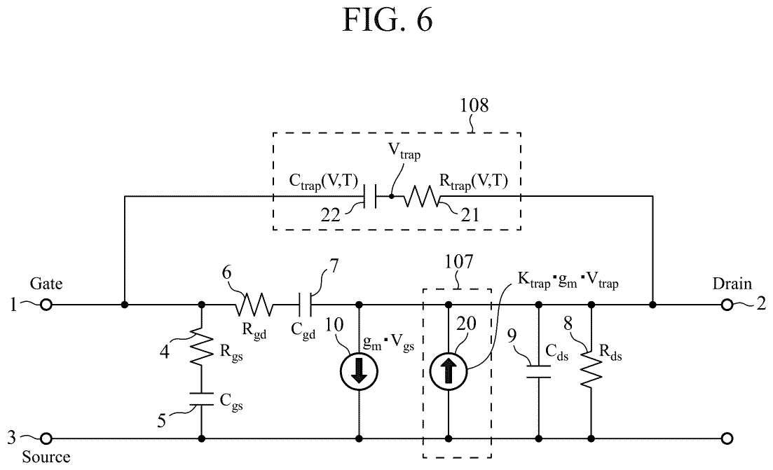

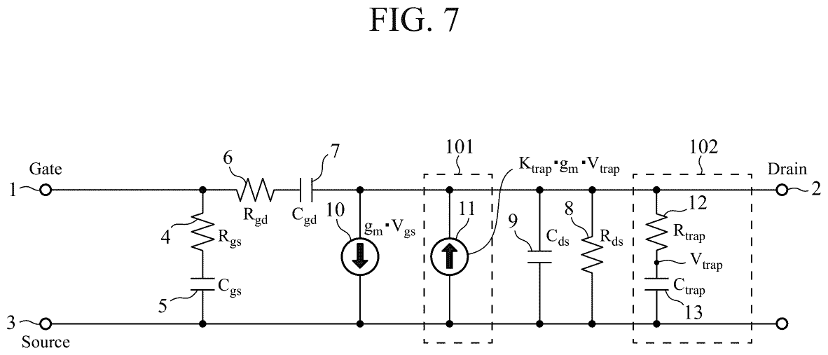

Next, a transistor equivalent circuit model according to a third embodiment will be described with reference to FIG. 6. As illustrated in FIG. 6, the transistor equivalent circuit model according to the third embodiment includes a gate electrode 1, a drain electrode 2, a source electrode 3, a gate source resistor (Rgs) 4, a gate source capacitor (Cgs) 5, a gate drain resistor (Rgd) 6, a gate drain capacitor (Cgd) 7, a drain source resistor (Rds) 8, a drain source capacitor (Cds) 9, a current source (gₘ·Vgs) 10, a trap equivalent circuit 107 represented by a current source (Ktrap*gₘ*Vtrap) 20 indicating the influence of current due to trap, and a trap equivalent circuit 108 that includes a trap resistor (Rtrap (V, T)) 21 and a trap capacitor (Ctrap (V, T)) 22 and represents a time constant of a trap disposed between the gate electrode and the drain electrode. As described above, in the transistor equivalent circuit model according to the third embodiment, the trap equivalent circuit 108 representing the time constant of the trap is disposed at a position different from the case of the first embodiment. With such a configuration, in the third embodiment, the influence of the trap between the gate electrode and the drain electrode can be calculated. Even in the case of the trap between the gate electrode and the drain electrode as in the third embodiment, since the trap level is affected by the output voltage proportional to the electric field intensity, it is conceivable to consider a physical model of the Poole-Frenkel effect for modifying the influence of the electric field intensity. When it is taken into consideration, the time constant of the trap may be modified by the output voltage and the temperature using Equations (5), (6), and (7) described in the first embodiment.

Since the hardware configuration and the simulation method of the transistor characteristics simulation device according to the third embodiment are similar to those in the first embodiment, the description thereof will be omitted.

Note that the embodiments can be combined, and the embodiments can be appropriately modified or omitted.

### INDUSTRIAL APPLICABILITY

The transistor characteristics simulation technique of the present disclosure can be used as a technique for simulating characteristics of a transistor such as a MOSFET having an insulator.

### REFERENCE SIGNS LIST

1: gate electrode, 2: drain electrode, 3: source electrode, 4: gate source resistor, 5: gate source capacitor, 6: gate drain resistor, 7: gate drain capacitor, 8: drain source resistor, 9: drain source capacitor, 10: current source, 11: current source, 12: trap resistor, 13: trap capacitor, 14: current source, 15: trap resistor, 16: trap capacitor, 17: current source, 18: trap resistor, 19: trap capacitor, 20: current source, 21: trap resistor, 22: trap capacitor, 101 to 108: trap equivalent circuit, 201: processor, 202: memory

1. A transistor characteristic simulation device using a transistor equivalent circuit model, wherein
the transistor equivalent circuit model comprises a trap equivalent circuit for modifying a level of a trap of a transistor by an electric field intensity, the trap equivalent circuit corresponding to a physical model of Poole-Frenkel effect.

2. The transistor characteristic simulation device using the transistor equivalent circuit model according to claim 1, wherein
the trap equivalent circuit includes circuit parameters that have voltage dependence and temperature dependence and represent a time constant of the trap, and corresponds to the physical model of Poole-Frenkel effect by the time constant of the trap being modified depending on voltage and temperature.

3. The transistor characteristic simulation device using the transistor equivalent circuit model according to claim 2, wherein
the voltage dependence and the temperature dependence are expressed by one exponential function.

4. The transistor characteristic simulation device using the transistor equivalent circuit model according to claim 3, wherein
the voltage dependence is a dependence on an output voltage proportional to an electric field strength of a channel, and
the temperature dependence is a dependence on a channel temperature.

5. The transistor characteristic simulation device using the transistor equivalent circuit model according to claim 1, wherein
the trap equivalent circuit includes a circuit representing the time constant of the trap, and
the circuit representing the time constant of the trap is provided between a drain electrode and a source electrode, between a gate electrode and the source electrode, or between the gate electrode and the drain electrode.

6. The transistor characteristic simulation device using the transistor equivalent circuit model according to claim 2, wherein
the trap equivalent circuit includes a circuit representing the time constant of the trap, and
the circuit representing the time constant of the trap is provided between a drain electrode and a source electrode, between a gate electrode and the source electrode, or between the gate electrode and the drain electrode.

7. The transistor characteristic simulation device using the transistor equivalent circuit model according to claim 3, wherein
the trap equivalent circuit includes a circuit representing the time constant of the trap, and
the circuit representing the time constant of the trap is provided between a drain electrode and a source electrode, between a gate electrode and the source electrode, or between the gate electrode and the drain electrode.

8. The transistor characteristic simulation device using the transistor equivalent circuit model according to claim 4, wherein
the trap equivalent circuit includes a circuit representing the time constant of the trap, and
the circuit representing the time constant of the trap is provided between a drain electrode and a source electrode, between a gate electrode and the source electrode, or between the gate electrode and the drain electrode.

9. The transistor characteristic simulation device using the transistor equivalent circuit model according to claim 5, wherein
the circuit representing the time constant of the trap comprises a resistor and a capacitor, and
both the resistor and the capacitor have voltage dependence and temperature dependence.

10. The transistor characteristic simulation device using the transistor equivalent circuit model according to claim 6, wherein
the circuit representing the time constant of the trap comprises a resistor and a capacitor, and
both the resistor and the capacitor have voltage dependence and temperature dependence.

11. The transistor characteristic simulation device using the transistor equivalent circuit model according to claim 7, wherein
the circuit representing the time constant of the trap comprises a resistor and a capacitor, and both the resistor and the capacitor have voltage dependence and temperature dependence.

12. The transistor characteristic simulation device using the transistor equivalent circuit model according to claim 8, wherein
the circuit representing the time constant of the trap comprises a resistor and a capacitor, and
both the resistor and the capacitor have voltage dependence and temperature dependence.

13. A transistor characteristic simulation method performed by a transistor characteristic simulation device, the transistor characteristic simulation method comprising:
receiving setting values related to various parameters of a transistor circuit model;
performing a simulation using a transistor equivalent circuit model comprising a trap equivalent circuit for modifying a level of a trap of a transistor by an electric field intensity, the trap equivalent circuit corresponding to a physical model of Poole-Frenkel effect, and the received setting values; and
outputting a result of the simulation.

14. A non-transitory computer readable medium storing transistor characteristic simulation program causing a computer to execute simulation of a transistor characteristic by using a transistor equivalent circuit model comprising a trap equivalent circuit for modifying a level of a trap of a transistor by an electric field intensity, the trap equivalent circuit corresponding to a physical model of Poole-Frenkel effect.
